(19) United States
(12) Patent Application Publication
(10) Pub. No.: US 2026/0185870 A1
(43) Pub. Date: Jul. 2, 2026

(54) INFORMATION PROCESSING APPARATUS, INFORMATION PROCESSING METHOD, AND COMPUTER-READABLE RECORDING MEDIUM

(71) Applicant: NEC Corporation, Tokyo (JP)

(72) Inventors: Yoshiyuki YAJIMA, Tokyo (JP); Daisuke IKEFUJI, Tokyo (JP); Hemant Shivsagar PRASAD, Tokyo (JP)

(73) Assignee: NEC Corporation, Tokyo (JP)

(21) Appl. No.: 19/401,588

(22) Filed: Nov. 26, 2025

(30) Foreign Application Priority Data
Dec. 4, 2024 (JP) 2024-211554

(51) Int. Cl. G01H 9/00; G06F 30/20

(52) U.S. Cl. CPC G01H 9/004; G06F 30/20

(57) ABSTRACT

An information processing apparatus includes a presetting unit that sets an initial value of a missing portion in observation data output from a sensor, a simulation data evaluation unit that acquires results of a plurality of simulations executed assuming an observation environment and evaluates, for each simulation, similarity between observation data including the missing portion and data obtained in the simulation, and a missing value estimation unit that estimates a value of the missing portion using data obtained in the simulation having the highest similarity.

This application is based upon and claims the benefit of priority from Japanese patent application No. 2024-211554, filed on Dec. 4, 2024, the disclosure of which is incorporated herein in its entirety by reference.

### TECHNICAL FIELD

The present disclosure relates to a technique for compensating for loss of sensor data.

### BACKGROUND ART

In recent years, a technique for detecting vibration using an optical fiber cable has been proposed. For example, JP 2024-510957 A discloses a system that detects ground vibration by an optical fiber cable laid on the ground and provides information regarding an earthquake using the detected vibration.

In addition, if an optical fiber cable laid on a road is used, vibration data of each vehicle traveling on the road can be detected in real time. For this reason, WO 2017/072505 A1 proposes a system that specifies a traveling trajectory of each vehicle using vibration data detected from a road and visualizes traffic flow. According to such a system, a road manager can accurately monitor a situation of the road, in such a way that smooth traffic is promoted.

### SUMMARY

However, in vibration detection using an optical fiber cable, due to characteristics of the optical fiber cable, in a case where a traveling speed of a vehicle is low, for example, in the case of congestion, vibration becomes small, and traveling vibration of the vehicle cannot be detected. In such a case, a traveling trajectory disappears at the corresponding place in traffic flow data, a missing portion is generated, and it is difficult to visualize traffic flow.

As a result, speed information in a section in which congestion occurs becomes unknown, and information such as a period required for passing through the section in which congestion occurs cannot be accurately provided to a driver. In addition, loss occurs even in a road structure in which it is difficult to detect vibration of a vehicle with an optical fiber cable. For example, in a section including a structure such as a bridge or an elevated structure, the entire structure is vibrated by a traveling vehicle, and thus, vibration of the vehicle is buried in the vibration of the structure, a traveling trajectory cannot be observed, and a missing portion occurs in traffic flow data, which makes it difficult to visualize and monitor the traffic flow.

An object of the present disclosure is to compensate for a missing portion in a case where the missing portion occurs in observation data acquired from a sensor.

In order to achieve the above object, an information processing apparatus according to one aspect of the present disclosure includes
a presetting unit that sets an initial value of a missing portion in observation data output from a sensor,
a simulation data evaluation unit that acquires results of a plurality of simulations executed assuming an observation environment, and evaluates, for each of the simulations, similarity between the observation data including the missing portion and data obtained in the simulation, and
a missing value estimation unit that estimates a value of the missing portion using data obtained in the simulation having the highest similarity.

In order to achieve the above object, an information processing method according to one aspect of the present disclosure includes
a presetting step of setting an initial value of a missing portion in observation data output from a sensor,
a simulation data evaluation step of acquiring results of a plurality of simulations executed assuming an observation environment, and evaluating, for each of the simulations, similarity between the observation data including the missing portion and data obtained in the simulation, and
a missing value estimation step of estimating a value of the missing portion using data obtained in the simulation having the highest similarity.

Further, in order to achieve the above object, a computer-readable recording medium according to one aspect of the present disclosure records a program including commands for causing
a computer to execute
a presetting step of setting an initial value of a missing portion in observation data output from a sensor,
a simulation data evaluation step of acquiring results of a plurality of simulations executed assuming an observation environment, and evaluating, for each of the simulations, similarity between the observation data including the missing portion and data obtained in the simulation, and
a missing value estimation step of estimating a value of the missing portion using data obtained in the simulation having the highest similarity.

As described above, according to the present disclosure, in a case where a missing portion occurs in observation data acquired from a sensor, it is possible to compensate for the missing portion.

### BRIEF DESCRIPTION OF THE DRAWINGS

FIG. 1 is a configuration diagram illustrating a schematic configuration of an example of an information processing apparatus;

FIG. 2 is a configuration diagram specifically illustrating a configuration of an example of the information processing apparatus;

FIG. 3 is a view illustrating an example of observation data;

FIG. 4 is a view illustrating an example of a prior distribution;

FIG. 5 is a view illustrating an example of a result of a traffic flow simulation;

FIGS. 6A to 6D are views for explaining determination of a traffic flow parameter set;

FIG. 7 is an explanatory diagram for explaining particle filtering processing in a case where one traffic flow parameter set is finally determined;

FIGS. 8A and 8B are views illustrating an example of observation data (average speed) and a posterior probability of each traffic flow parameter set;

FIG. 9 is a view illustrating an example of replacement of a missing portion in the observation data;

FIG. 10 is a flowchart indicating operation of an example of the information processing apparatus; and

FIG. 11 is a block diagram illustrating an example of a computer that implements the information processing apparatus.

### EXAMPLE EMBODIMENT

### Example Embodiment

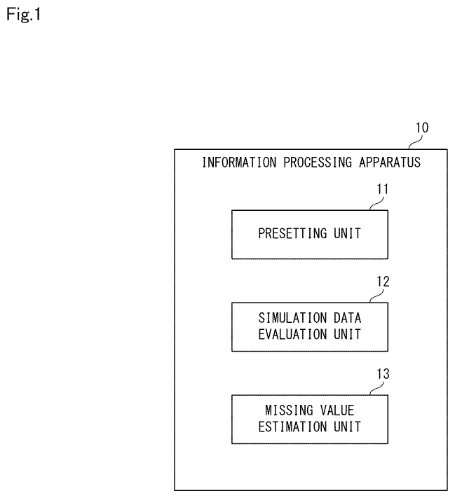

Hereinafter, an information processing apparatus, an information processing method, and a program in an example embodiment will be described with reference to FIGS. 1 to 11.

### [Apparatus Configuration]

First, a schematic configuration of an example of an information processing apparatus will be described with reference to FIG. 1. FIG. 1 is a configuration diagram illustrating a schematic configuration of an example of the information processing apparatus.

An information processing apparatus 10 illustrated in FIG. 1 is an apparatus for compensating for loss of observation data. As illustrated in FIG. 1, the information processing apparatus 10 includes a presetting unit 11, a simulation data evaluation unit 12, and a missing value estimation unit 13.

The presetting unit 11 sets an initial value of a missing portion in observation data output from a sensor. The simulation data evaluation unit 12 acquires results of a plurality of simulations executed assuming an observation environment, and evaluates, for each of the simulations, similarity between the observation data including the missing portion and data obtained in the simulation. The missing value estimation unit 13 estimates a value of the missing portion using data obtained in the simulation having the highest similarity.

In this manner, in a case where a missing portion occurs in the observation data acquired from the sensor, the information processing apparatus 10 can compensate for the missing portion. In addition, the compensation is performed with a value obtained in the selected simulation as a simulation that most reproduces the observation data among simulations under different conditions. Thus, estimation accuracy of the value of the missing portion is high.

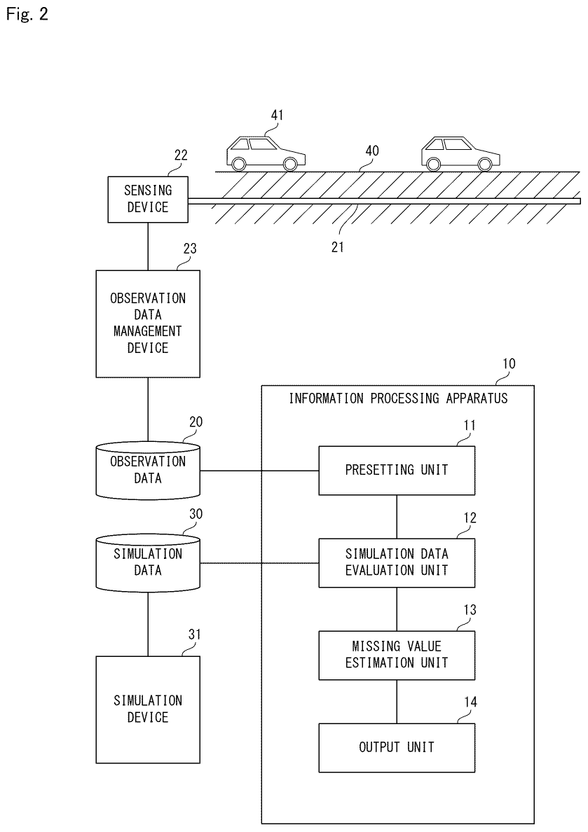

Next, a configuration and a function of an example of the information processing apparatus will be specifically described with reference to FIGS. 2 to 7. FIG. 2 is a configuration diagram specifically illustrating a configuration of an example of the information processing apparatus.

As illustrated in FIG. 2, the information processing apparatus 10 is connected to databases 20 and 30 via a network, or the like. The database 20 stores observation data as described later. The database 30 stores simulation data as described later. The databases 20 and 30 are constructed by a server device, a storage device, and the like. Note that the databases 20 and 30 may be constructed inside the information processing apparatus 10.

As illustrated in FIG. 2, in the example embodiment, a sensing device 22 using an optical fiber cable 21 laid on a road 40 is used as the sensor. Hereinafter, the sensing device 22 will be described as an example of the sensor.

The sensing device 22 enters pulsed light into the optical fiber cable 21. Then, if vibration occurs by a vehicle 41 traveling on the road 40, backscattered light is generated in the optical fiber cable 21, and thus, the generated backscattered light is incident on the sensing device 22. The sensing device 22 specifies intensity of vibration, a position and time at which the vibration has occurred from phase change of the incident backscattered light, and outputs data indicating the specified position and time of the vibration to an observation data management device 23.

The observation data management device 23 analyzes data output from the sensing device 22 to extract a traveling trajectory of each vehicle traveling on the road 40, and calculates an average speed of the vehicle 41 at each point on the road 40 using the extracted traveling trajectory of each vehicle. The observation data management device 23 outputs, as the observation data, average speed data indicating an average speed of the vehicles 41 traveling on the road 40 calculated using the data from the optical fiber cable 21. The observation data (average speed data) output from the observation data management device 23 is stored in the database 20.

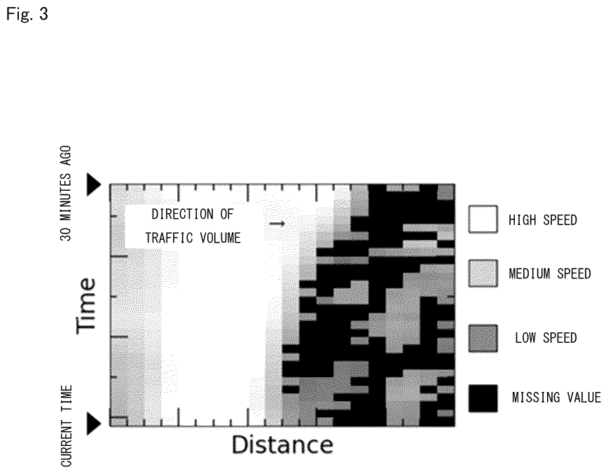

FIG. 3 is a view illustrating an example of the observation data. In the example of FIG. 3, average speed data in the past 30 minutes by optical fiber sensing is indicated as the observation data. FIG. 3 indicates elapsed time (minutes) from reference time on a vertical axis, and indicates a distance (km) from a reference position on a horizontal axis. In FIG. 3, a black portion is a missing portion. In FIG. 3, the missing portion is generated by the average speed of the vehicles 41 being significantly low due to congestion, or the like, and the vibration being weakened.

In addition, in FIG. 2, a simulation device 31 sets a plurality of traffic flow parameter sets of a traffic flow theoretical model, and executes a traffic flow simulation for each of the traffic flow parameter sets. The simulation device 31 stores data of the traffic flow simulation for each traffic flow parameter set in the database 30 as simulation data. Note that a detailed function of the simulation device 31 will be described later. As illustrated in FIG. 2, the information processing apparatus 10 includes an output unit 14 in addition to the presetting unit 11, the simulation data evaluation unit 12, and the missing value estimation unit 13 described above.

In the example embodiment, the presetting unit 11 sets a prior distribution such that a probability changes according to the value, and sets an initial value of the missing portion in the observation data according to the set prior distribution. Furthermore, as described above, in a case where the average speed data of the vehicles 41 is used as the observation data, the presetting unit 11 sets a prior distribution such that the probability changes according to the average speed of the vehicles 41.

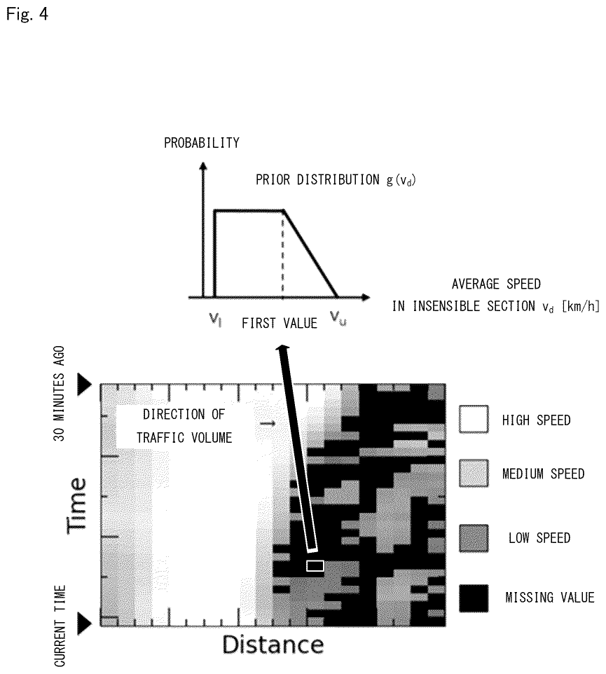

For example, the presetting unit 11 sets a prior distribution such that the probability is constant from a lower limit value vₗ to a first value, and the probability is decreased from the first value to an upper limit value vu as a possible value of the observation data in each data segment that is a missing portion, for example. FIG. 4 is a view illustrating an example of the prior distribution. In FIG. 4, an “insensible section” means a data segment that is a missing portion in the observation data, and an “average speed v_{d} in the insensible section” means an average speed in the missing portion in the observation data.

In the example of FIG. 4, the presetting unit 11 first sets the first value of the average speed that is the observation data to a preset value. In the example of FIG. 4, specifically, the first value is set to 20 [km/h]. This is because, under the measurement environment of the road in FIG. 4, if the average speed is equal to or less than 20 [km/h], the vibration is weak as described above, which results in the missing portion. Note that the first value depends on an installation environment of the sensor that has performed the measurement and settings of the sensing device and a sensing data analysis device. Thus, the first value is determined from a lower limit value of an observation value that becomes a non-missing value. As the lower limit value vₗ, 0 [km/h], which is the lowest value among the speeds that can occur during traffic congestion, is uniformly set for all the data segments that are missing portions.

In addition, the presetting unit 11 compensates for a value by interpolation or extrapolation for each data segment of the missing portion of the observation data, and sets the compensated interpolation/extrapolation value as the upper limit value vu. In the case of FIG. 4, the data segment is one cell defined by certain time and a certain road section. Although the interpolation/extrapolation value is a speed approximate to the non-missing value, there is a high possibility that the insensible section is a section in which the vibration of the vehicle 41 is weak, and there is a possibility that the average speed is equal to or less than 20 [km/h] in the case of FIG. 4. For this reason, the average speed in the insensible section is considered to be the interpolation/extrapolation value even if the average speed is high, and thus, the presetting unit 11 sets the compensated interpolation/extrapolation value to the upper limit value vu. With this setting, the upper limit value vu becomes a different value in each data segment of the missing portion. In a case where the upper limit value vu is equal to or less than the first value, a uniform distribution in which the first value is set as the upper limit value and a range from the lower limit value to the first value is set as a domain, is set as the prior distribution.

The simulation data evaluation unit 12 calculates, for each of a plurality of simulations executed assuming an observation environment, similarity indicating similarity between a value of observation data including a value obtained by the prior distribution of the missing portion and data obtained by the simulation. Then, the simulation data evaluation unit 12 performs evaluation using the similarity.

Specifically, before the processing by the simulation data evaluation unit 12 is performed, the simulation device 31 executes a traffic flow simulation for each of the plurality of set traffic flow parameter sets. Hereinafter, processing by the simulation device 31 will be described in detail.

The simulation device 31 first acquires setting data necessary for the traffic flow simulation. Examples of the setting data include a road parameter set, a traffic flow parameter set, simulation condition information, and inflow amount time-series information.

The road parameter set is a parameter set to be used when a simulation model (road model) of a target road is constructed in a traffic flow simulation to which a traffic flow theoretical model is applied.

The traffic flow theoretical model is, for example, a stochastic Nishinari-Fukui-Schadschneider (S-NFS) model. Specifically, the S-NFS model is a model in which behavior for each vehicle is described by a probabilistic cell automaton (CA).

For details of the S-NFS model, refer to Reference Document 1 (Satoshi Sakai, Katsuhiro Nishinari, Shinji Iida, “A new stochastic cellular automaton model on traffic flow and its jamming phase transition”, J. Phys. A: Math.Gen. 39 (2006) 15327-15339, [searched on May 14, 2024], Internet <URL: https://doi.org/10.48550/arXiv.cond-mat/0611455).

However, the traffic flow theoretical model based on the CA model is not limited to the S-NFS model, and there are also a Nishinari-Fukui-Schadschneider model (Reference Document 2: Katsuhiro Nishinari, Minoru Fukui, & Andreas Schadschneider, “A Stochastic Cellular Automaton Model for Traffic Flow with Multiple Metastable States”, J. Phys. A: Math.Gen. 37 (2004) 3101-3110, [searched on May 21, 2024], Internet <URL: https://iopscience.iop.org/article/10.1088/0305-4470/37/9/003>) and a Nagel-Schrechenberg model (Reference Document 3: Kai Nagekl & Michael Schreckenberg, “A Cellular Automaton Model for Freeway Traffic”, J. Phys. I France. 2 (1992) 2221-2229, [searched on May 21, 2024], Internet <URL: https://jp1.journaldephysique.org/en/articles/jp1/abs/1992/12/jp1v2p2221/jp1v2p2221.html>).

The traffic flow parameter set is a parameter set of the traffic flow theoretical model that is set when the traffic flow simulation is executed. Specifically, in the S-NFS model, a speed of each vehicle is determined based on the following (1) to (5).
(1) a maximum speed Vmax of a target road
(2) a speed of one vehicle ahead of the vehicle and an inter-vehicle distance with the vehicle: rear-end collision avoidance
(3) a random brake occurrence probability p: one-step deceleration (random brake effect)
(4) a slow start occurrence probability q: an inter-vehicle distance at a time point of a previous step (a time delay of inertia/reaction, a slow start effect))
(5) a likelihood probability r: a (future likelihood) speed using an inter-vehicle distance with a vehicle S vehicles ahead of the vehicle For example, S=2 in the case of the probability r, and S=1 in the case of the probability 1−r.

Thus, as the traffic flow parameter set to be adjusted to reproduce the measured traffic flow, at least parameters such as a maximum speed V_{BN} in a bottleneck, a random brake occurrence probability p_{BN} in the bottleneck, a random brake occurrence probability p outside the bottleneck, a slow start occurrence probability q, and a likelihood probability r are used. The bottleneck is a section in which the vehicle speed decreases or a section in which traffic congestion occurs, for example, a section such as an uphill, a sag, a tunnel, or a tollgate.

As an example of the traffic flow parameter set (parameter set example), it is conceivable that 1 cell is set at 10 [m] (meter), a time step width is set at 1.8 [second], speed resolution is set at 20 [km/h] (kilometer per hour) (=10 [m]/1.8 [second]=50/9 [m/second]), the maximum speed V_{BN} in the bottleneck is set at 20, 40, and 60 [km/h] (3 ways), the random brake occurrence probability p outside the bottleneck is set to be incremented by 0.05 (12 ways) in a range from 0.05 to 0.6, the random brake occurrence probability p_{BN} in the bottleneck is set at the same value as p, the slow start occurrence probability q is set to be incremented by 0.1 (8 ways) in a range from 0.1 to 0.8, and the likelihood probability r is set to be incremented by 0.03 (9 ways) in a range from 0.75 to 0.99. Note that, in the case of the above-described settings, the traffic flow parameter sets are 2592 sets (=3×12×8×9).

The simulation condition information is information indicating a simulation condition to be used in the traffic flow simulation. Examples of the simulation condition information include simulation end time and an initial condition.

The inflow amount time-series information is information representing a time-series inflow amount of the target road. The inflow amount time-series information is, for example, a value obtained by measuring the number of vehicles (time-series data) per unit time flowing into a start point (point of 0 [km]) of the target road by a traffic counter.

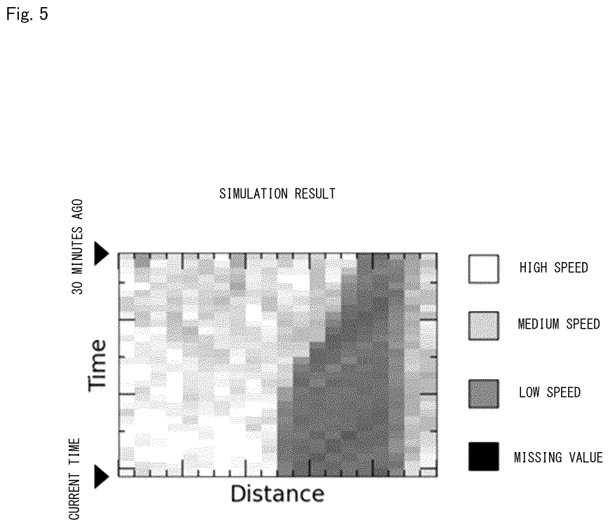

Next, the simulation device 31 executes the traffic flow simulation for each of the plurality of different traffic flow parameter sets in a set period. The set period is a period set in advance in the past from a current time point, and for example, a period from 10 to 60 [minutes] in the past from the current time point can be considered. However, the set period is not limited to the above-described period. In the example of the traffic flow parameter set described above, the simulation device 31 executes the traffic flow simulation up to 2592 times. FIG. 5 is a view illustrating an example of a result of the traffic flow simulation. The simulation device 31 stores the obtained result (hereinafter, referred to as “simulation data”) of the traffic flow simulation for each traffic flow parameter set in the database 30.

The simulation data evaluation unit 12 first acquires a result (simulation data) of the traffic flow simulation by the simulation device 31 from the database 30. Then, in the observation data, if the m-th section at time t is a missing value, the simulation data evaluation unit 12 calculates a weighted likelihood by the prior distribution as the similarity using the following expression 1 for each traffic flow simulation. In a case where the section is not a missing value, a likelihood is calculated using the following expression 2 as the similarity.

$$Weighted likelihood {ℒ}_{m , t} ( {θ}_{n} ) = {\int }_{{v}_{l}}^{{v}_{u}} g ( {v}_{a} ) f ( {v}_{d} - {v}_{m , t}^{sim} ( {θ}_{n} ) ) {dv}_{a} \qquad [ Math . 1 ]$$

$$Likelihood {ℒ}_{m , t} ( {θ}_{n} ) = f ( {v}_{m , t}^{obs} - {v}_{m , t}^{sim} ( {θ}_{n} ) ) \qquad [ Math . 2 ]$$

In the foregoing expression 1, g(v_{d}) is the prior distribution set by the presetting unit 11. f(v_{d}−v^{sim}_{m,t}(θₙ)) is a function for evaluating the similarity (error) between the speed v_{d} in the data missing portion and the average speed obtained by the traffic flow simulation with the n-th traffic flow parameter set θₙ in the m-th section at time t. This function returns a smaller value as the error is larger, and returns a larger value as the error is smaller. In other words, the similarity represents an error in the average speed between the observation data and the traffic flow simulation. Expression 2 is similarly a function for evaluating similarity (error) between the average speed observation value v^{obs}_{m,t} in the m-th section at time t and the average speed obtained by the traffic flow simulation with the n-th traffic flow parameter set θₙ in the m-th section at time t.

The likelihood in all the road sections is expressed by the following expression 3.

$${ℒ}_{t} ( {θ}_{n} ) = {\prod }_{m} {ℒ}_{m , t} ( {θ}_{n} ) \qquad [ Math . 3 ]$$

A missing value estimation unit 13 first determines a traffic flow simulation to be used for estimating the missing value by using the similarity for each traffic flow simulation calculated by the simulation data evaluation unit 12.

Specifically, the missing value estimation unit 13 calculates at least one or all of a posterior probability distribution, a maximum posterior probability, and an expected value of the posterior probability distribution of the traffic flow model parameters using the similarity for each traffic flow parameter set in the set period. Then, the missing value estimation unit 13 determines a traffic flow simulation to be used for estimation of the missing value, that is, a traffic flow parameter set based on the calculation result.

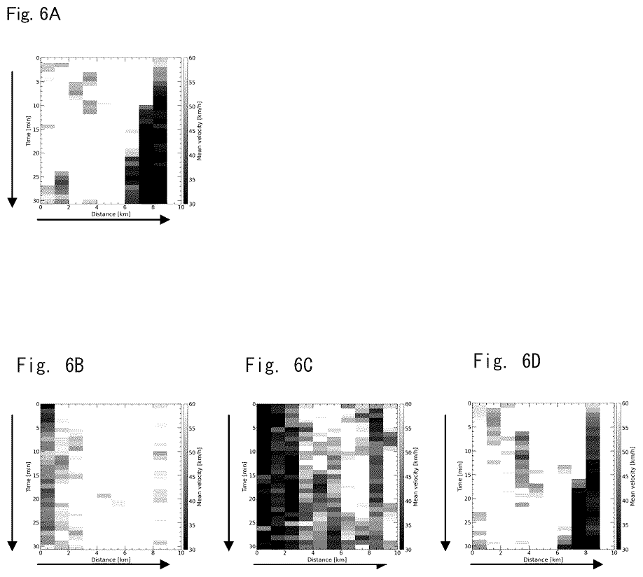

FIG. 6A to 6D are views for explaining determination of the traffic flow parameter set. FIG. 6A illustrates change in average speed based on the traffic flow measurement data. FIG. 6B, FIG. 6C, and FIG. 6D represent change in the average speed based on the traffic flow simulation data. In each of FIG. 6A to FIG. 6D, a vertical axis represents time flow, and a horizontal axis represents a direction of the traffic flow and a distance from the start point. In addition, the average speed of the vehicles is colored with different colors from 30 to 60 [km/h]. In other words, the average speed of the vehicles in each of 1 [min] and 1 [km] sections in the past 30 [min] is illustrated.

Further, FIG. 6B is a view obtained by setting the traffic flow parameter set as the probability (p, q, r)=(0.10, 0.8, 0.75). FIG. 6C is a view obtained by setting the traffic flow parameter set as the probability (p, q, r)=(0.55, 0.6, 0.84). FIG. 6D is a view obtained by setting the traffic flow parameter set as the probability (p, q, r)=(0.35, 0.2, 0.99).

FIG. 6A and FIG. 6D have high similarity at each time and each point, and thus, it can be determined that the traffic flow parameter set (0.35, 0.2, 0.99) of FIG. 6D is optimal. In this way, in as many sections as possible, traffic flow simulation data having a low error rate with respect to the average speed based on the observation data (traffic flow measurement data), that is, similar traffic flow simulation data is selected.

As a reason for using an error rate of the average speed as the similarity, for example, in a case where the error rate is allowed to be up to 10 [%] (percent), if the average speed in the traffic flow measurement data is 100 [km/h], an error up to ±10 [km/h] can be allowed for the average speed of the traffic flow simulation data. On the other hand, if the average speed in the traffic flow measurement data is 30 [km/h], an error of only ±3 [km/h] can be allowed for the average speed in the traffic flow simulation data. From the above, it is considered that the error rate of the average speed is suitable as an index of the similarity (matching degree) of congestion (low speed event). In other words, in order to focus on the low speed event, the error rate of the average speed is used to impose a larger penalty on a degree of mismatch in a low speed region than in a high speed region. As the similarity, an average flow rate or an average density may be used in addition to the average speed, or these may be combined.

Next, determination processing of the traffic flow parameter set by the missing value estimation unit 13 will be described in detail. An example of the determination processing of the traffic flow parameter set includes processing using a particle filter. In this case, the missing value estimation unit 13 executes the particle filtering processing by using the similarity for each traffic flow parameter set, and determines the traffic flow parameter set based on a frequency distribution of the particles.

The particle filtering processing is executed for each time t (a plurality of time t₁ to t_{N} (N is a positive integer of equal to or more than 2)) set in the set period for each piece of simulation data with a plurality of different traffic flow parameter sets.

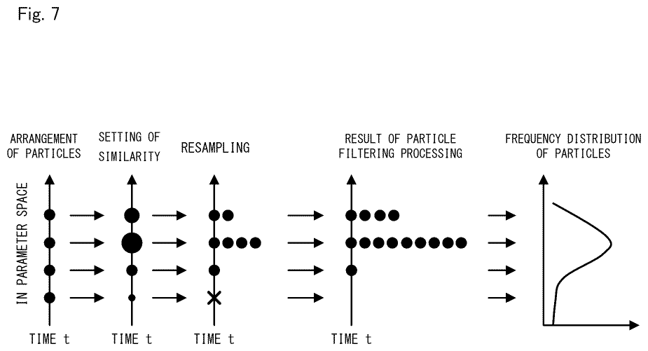

FIG. 7 is an explanatory diagram for explaining particle filtering processing in a case where one traffic flow parameter set is finally determined. In the particle filtering processing, first, as illustrated in FIG. 7, particles corresponding to the traffic flow parameter sets are arranged at sampled positions in a parameter space.

For example, it is assumed that a five-dimensional real space including a set of five parameters of the maximum speed V_{BN} in the bottleneck, the random brake probability p_{BN} in the bottleneck, the random brake probability p outside the bottleneck, the slow start occurrence probability q, and the likelihood probability r is the parameter space of the traffic flow parameter set.

In addition, in the traffic flow parameter set example, in the case of paragraph [0039] described above, 2593 parameter sets are sampled by grid search. Thus, 2593 sets of parameters are extracted from the 5-dimensional real space. The particles of the particle filter are placed at specific locations in the 5-dimensional real space constituted with values corresponding to the parameters extracted from the 5-dimensional real space, e.g. (V_{BN}, p_{BN}, p, q, r)=(20, 0.05, 0.1, 0.1, 0.75).

Next, as illustrated in FIG. 7, the similarity between the observation data and the traffic flow simulation data is set for the particles of the traffic flow parameter set at the target time t. As the similarity, the likelihood obtained by expression 3 is used. Note that a higher similarity (weight) is set for particles with a higher traffic flow parameter set. In the example of FIG. 7, the black circle becomes larger as the similarity is higher.

Next, in the particle filtering processing, resampling is performed according to the weights of the particles. In other words, the number of particles to be arranged increases at positions where particles having large weights exist in the parameter space while maintaining the total number of particles. Conversely, the number of particles to be arranged decreases at positions where particles having small weights exist. As a result, many particles are arranged in the traffic flow parameter set having a high similarity with the observation data (the observation data can be well reproduced), and the traffic flow parameter set having a low similarity finally disappears.

If the particle filtering processing is completed from the time t₁ to the time t_{N} of the traffic flow simulation data, as illustrated in FIG. 7, many particles are arranged in the traffic flow parameter set having a high similarity with the observation data.

Thereafter, the missing value estimation unit 13 calculates statistical information (at least one or all of a posterior probability distribution, a maximum posterior probability, and an expected value of the posterior probability distribution) for each traffic flow parameter set based on the frequency distribution of particles in the traffic flow parameter set illustrated in FIG. 7. In the case of such a traffic flow parameter set, as a result of the particle filtering processing, a simultaneous distribution is obtained in the five-dimensional real space which is the parameter space. For example, in a traffic flow parameter set having a high degree of reproduction of traffic flow, a value of the simultaneous distribution is high, and thus, the missing value estimation unit 13 obtains a marginal distribution in each traffic flow parameter from the simultaneous distribution having a high value, and acquires a posterior probability distribution of each traffic flow parameter as the statistical information.

Then, the missing value estimation unit 13 compares the statistical information calculated for each of the traffic flow parameter sets with each other, and determines (estimates) the traffic flow parameter set most similar to the observation data based on the comparison result. For example, the missing value estimation unit 13 determines a traffic flow parameter having the maximum posterior probability as an optimal traffic flow parameter set.

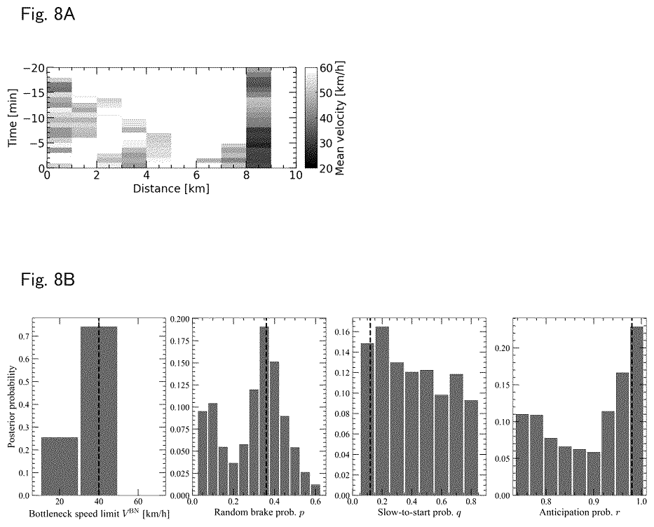

FIGS. 8A and 8B are views illustrating an example of the observation data (average speed) and a posterior probability of each traffic flow parameter set. FIG. 8A illustrates observation data, and the traffic flow parameter set is (V_{BN}, p_{BN}, p, q, r)=(40, 0.36, 0.36, 0.12, 0.98). FIG. 8B illustrates the maximum speed in the bottleneck, the random brake occurrence probability outside the bottleneck, the slow start occurrence probability, and the likelihood probability in the traffic flow parameter set. A broken line in FIG. 8B represents a correct value of the traffic flow parameter set. In the example of FIG. 8, it can be confirmed that a value with the maximum posterior probability is close to the correct value.

Subsequently, the missing value estimation unit 13 acquires simulation data corresponding to the determined traffic flow parameter set from the database 30, and specifies a portion corresponding to the missing portion of the observation data in the acquired simulation data. The value of the specified portion is the value of the estimated missing portion. Then, the missing value estimation unit 13 replaces the missing portion of the observation data with the estimated value.

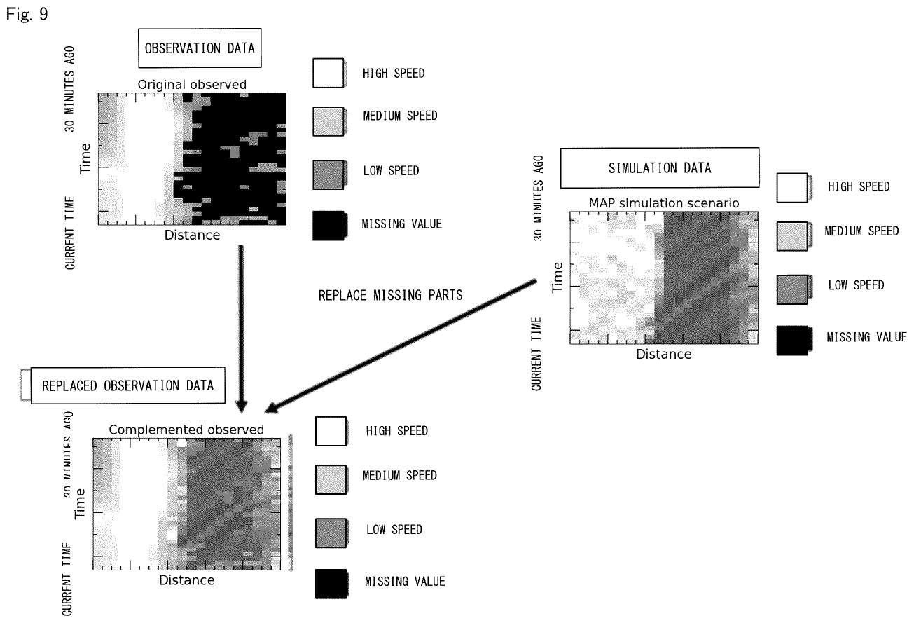

FIG. 9 is a view illustrating an example of replacement of the missing portion in the observation data. An upper part in FIG. 9 illustrates an example of the observation data including the missing portion. A middle part in FIG. 9 illustrates an example of the simulation data. A lower part in FIG. 9 illustrates an example of the observation data in which the missing portion is replaced with a value of the simulation data.

If the processing by the missing value estimation unit 13 is completed, the output unit 14 outputs the observation data in which the missing portion is replaced. Examples of the output destination include a management system, and the like, that manage roads.

### [Apparatus Operation]

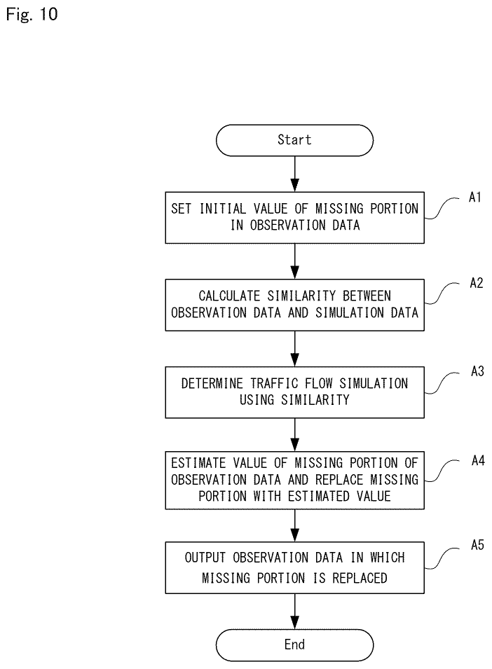

Next, operation of an example of the information processing apparatus will be described with reference to FIG. 10. FIG. 10 is a flowchart indicating operation of an example of the information processing apparatus. In the following description, FIGS. 1 to 9 will be appropriately referred to. In the example embodiment, an information processing method is performed by the information processing apparatus 10 being operated. Thus, description of the information processing method according to the example embodiment will be substituted with the following description of the operation of the information processing apparatus 10.

As indicated in FIG. 10, first, the presetting unit 11 sets a prior distribution, and sets an initial value of a missing portion in observation data according to the set prior distribution (step A1).

Specifically, in step A1, for example, the presetting unit 11 sets a prior distribution such that the probability is constant from the lower limit value vₗ to the first value, and the probability is decreased from the first value to the upper limit value vu as a possible value of the observation data (see FIG. 4).

Next, the simulation data evaluation unit 12 calculates, for each of the plurality of simulations executed assuming an observation environment, similarity indicating similarity between observation data including a value obtained by the prior distribution of the missing portion and data obtained by the simulation (step A2).

Specifically, in step A2, the simulation data evaluation unit 12 acquires a result (simulation data) of the traffic flow simulation by the simulation device 31 from the database 30. Then, for each traffic flow simulation, the simulation data evaluation unit 12 calculates the weighted likelihood using the above expression 1 and the likelihood using the above expression 2 as the similarity.

Next, the missing value estimation unit 13 evaluates the similarity between the observation data and each traffic flow simulation using the similarity for each traffic flow simulation calculated in step A2 by using the above expression 3, and determines a traffic flow simulation to be used for estimating the missing value (step A3).

Specifically, in step A3, the missing value estimation unit 13 calculates the statistical information of the traffic flow parameter set using the similarity for each traffic flow parameter set in the set period. Then, the missing value estimation unit 13 compares the statistical information calculated for each of the traffic flow parameter sets with each other, and determines (estimates) the traffic flow parameter set most similar to the observation data based on the comparison result. The traffic flow simulation executed using the determined traffic flow parameter set is used for estimation of the missing value.

Next, the missing value estimation unit 13 estimates the value of the missing portion of the observation data using the simulation data of the traffic flow simulation determined in step A3, and replaces the missing portion of the observation data with the estimated value (step A4).

Next, the output unit 14 outputs the observation data in which the missing portion is replaced in step A4 (step A5).

### Effects of Example Embodiment

As described above, in the example embodiment, if steps A1 to A5 are executed, the missing portion of the observation data acquired from the sensor is estimated with high accuracy. Furthermore, the missing portion is replaced with a value estimated with high accuracy, and thus, the observation data is data true to an actual phenomenon. Thus, according to the example embodiment, accuracy of visualization of the traffic flow also increases according to the observation data in which the missing portion is replaced.

### Modification

In the example described above, the presetting unit 11 sets the prior distribution indicated in FIG. 4, but the prior distribution is not limited thereto. The prior distribution may be set using, for example, a measurement value obtained by a sensor different from the sensor (for example, the fiber cable 21 and the sensing device 22). In this case, the presetting unit 11 sets a prior distribution such that the probability is maximized in a case where the observation data has the same value as the measurement value, the probability is increased from the lower limit value to the same value, and the probability is decreased from the same value to the upper limit value. Other sensors include an imaging device (camera), a loop coil, a traffic counter such as an ultrasonic sensor, a travel log from a probe car, and the like.

The prior distribution may be a uniform distribution from the lower limit value to the upper limit value without using the first value. The prior distribution of the uniform distribution corresponds to a case where there is no prior information at all regarding the missing portion of the observation data. Conversely, in a case where there is highly accurate prior information regarding the missing portion of the observation data, the missing portion may be set to take only a value corresponding to the prior information. This case is equivalent to applying a delta function to the prior distribution.

The prior distribution may be set using prior information about a road structure. For example, as described in the above paragraph [0005], in the case of average speed observation data using an optical fiber, data loss is likely to occur in a bridge or an elevated section. In the case of such a road structure, there is a high possibility that the observation data of the missing portion is similar to before and after the bridge or the elevated section. Thus, a prior distribution may be set by performing interpolation in a spatial direction before and after the missing portion such that the probability is maximized in a case where the estimated value by the interpolation has the same value as the observation data, the probability is increased from the lower limit value to the same value, and the probability is decreased from the same value to the upper limit value.

Furthermore, in the above-described example, the sensing device 22 using the optical fiber cable 21 is illustrated as a sensor, but the sensor is not limited to the above-described example. Examples of the sensor include a camera, an acceleration sensor, a pressure sensor, a temperature sensor, a wind direction sensor, a wind force sensor, a strain sensor, and a displacement sensor.

In addition, the observation data to be handled by the information processing apparatus 10 may be other than the average speed of the traffic flow. Other examples of the observation data include an average flow rate (average number of passing vehicles per unit time) and an average density (average number of vehicles per unit road length) in a traffic flow observation scene, an air pressure, an air temperature, a sea surface temperature, a wind direction, a wind speed, and acceleration, strain, displacement, and the like, in a structure monitoring scene.

### [Program]

An example of the program is a program for causing a computer to execute steps A1 to A5 indicated in FIG. 10. By installing the program in the computer and executing the program, the information processing apparatus 10 and the information processing method can be implemented. In this case, a processor of the computer functions as the presetting unit 11, the simulation data evaluation unit 12, the missing value estimation unit 13, and the output unit 14, and performs processing. Examples of the computer include a smartphone and a tablet terminal device in addition to a server device and a general-purpose PC.

Furthermore, the program may be executed by a computer system constructed by a plurality of computers. In this case, for example, each computer may function as any of the presetting unit 11, the simulation data evaluation unit 12, the missing value estimation unit 13, and the output unit 14.

### [Physical Configuration]

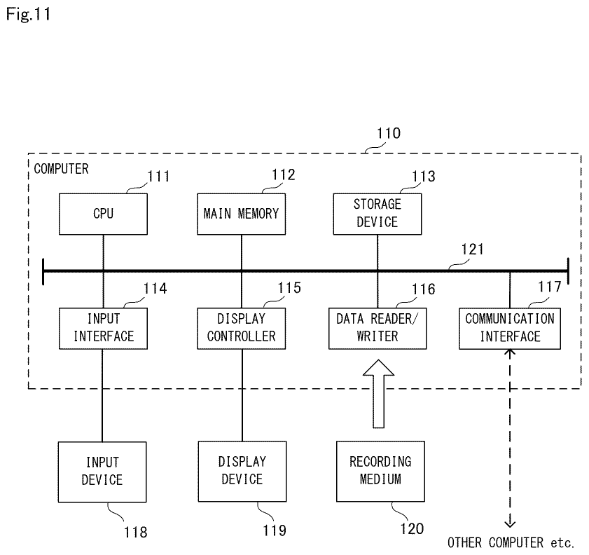

Here, the computer that implements the information processing apparatus by executing the program according to the example embodiment will be described with reference to FIG. 11. FIG. 11 is a block diagram illustrating an example of the computer that implements the information processing apparatus.

As illustrated in FIG. 11, a computer 110 includes a central processing unit (CPU) 111, a main memory 112, a storage device 113, an input interface 114, a display controller 115, a data reader/writer 116, and a communication interface 117. These units are data-communicably connected to each other via a bus 121.

Furthermore, the computer 110 may include a graphics processing unit (GPU) or a field-programmable gate array (FPGA) in addition to the CPU 111 or instead of the CPU 111. In this aspect, the GPU or the FPGA can execute the program in the example embodiment.

The CPU 111 loads the program according to the example embodiment, which is stored in the storage device 113 and configured by a code group, to the main memory 112, and executes each code in a predetermined order to perform various operations. The main memory 112 is typically a volatile storage device such as a dynamic random access memory (DRAM).

The program in the example embodiment is provided in a state of being stored in a computer-readable recording medium 120. The program in the present example embodiment may be distributed on the Internet connected via the communication interface 117.

Specific examples of the storage device 113 include a semiconductor storage device such as a flash memory in addition to a hard disk drive. The input interface 114 mediates data transmission between the CPU 111 and an input device 118 such as a keyboard and a mouse. The display controller 115 is connected to a display device 119 and controls display on the display device 119.

The data reader/writer 116 mediates data transmission between the CPU 111 and the recording medium 120, and reads a program from the recording medium 120 and writes a processing result in the computer 110 to the recording medium 120. The communication interface 117 mediates data transmission between the CPU 111 and another computer.

Specific examples of the recording medium 120 include general-purpose semiconductor storage devices such as compact flash (CF) (registered trademark) and a secure digital (SD), a magnetic recording medium such as a flexible disk, and an optical recording medium such as a compact disk read only memory (CD-ROM).

The information processing apparatus 10 may also be implemented by using hardware relevant to each unit, such as an electronic circuit, instead of the computer in which the program is installed. Moreover, part of the information processing apparatus may be implemented by the program, and the remaining part may be implemented by hardware. In the example embodiments, the computer is not limited to the computer illustrated in FIG. 11.

Some or all of the above-described example embodiments can be expressed by (Supplementary Note 1) to (Supplementary Note 18) described below, but are not limited to the following description.

### (Supplementary Note 1)

An information processing apparatus including:
a presetting unit that sets an initial value of a missing portion in observation data output from a sensor;
a simulation data evaluation unit that acquires results of a plurality of simulations executed assuming an observation environment, and evaluates, for each of the simulations, similarity between the observation data including the missing portion and data obtained in the simulation; and
a missing value estimation unit that estimates a value of the missing portion using data obtained in the simulation having the highest similarity.

### (Supplementary Note 2)

The information processing apparatus according to Supplementary Note 1, in which
the presetting unit sets the initial value by setting a prior distribution such that a probability changes according to a value, and
the simulation data evaluation unit performs evaluation by calculating similarity indicating similarity between a value of the observation data including a value obtained by the prior distribution of the missing portion and data obtained in the simulation.

### (Supplementary Note 3)

The information processing apparatus according to Supplementary Note 2, in which
the presetting unit sets the prior distribution such that the probability is constant from a lower limit value to a first value, and the probability is decreased from the first value to an upper limit value as a possible value of the observation data.

### (Supplementary Note 4)

The information processing apparatus according to Supplementary Note 2, in which
the presetting unit sets the prior distribution such that the probability is maximized in a case where the observation data has the same value as a measurement value obtained by a sensor different from the sensor, the probability is increased from a lower limit value to the same value, and the probability is decreased from the same value to an upper limit value.

### (Supplementary Note 5)

The information processing apparatus according to Supplementary Note 1, in which
the missing value estimation unit replaces the missing portion of the observation data with the estimated value.

### (Supplementary Note 6)

The information processing apparatus according to Supplementary Note 2, in which
a sensor is a sensing device using an optical fiber cable laid on a road,
the observation data is average speed data indicating an average speed of vehicles traveling on the road calculated using data from the optical fiber cable, and
the presetting unit sets a prior distribution such that the probability changes according to the average speed of the vehicles.

### (Supplementary Note 7)

An information processing method including:
a presetting step of setting an initial value of a missing portion in observation data output from a sensor;
a simulation data evaluation step of acquiring results of a plurality of simulations executed assuming an observation environment, and evaluating, for each of the simulations, similarity between the observation data including the missing portion and data obtained in the simulation; and
a missing value estimation step of estimating a value of the missing portion using data obtained in the simulation having the highest similarity.

### (Supplementary Note 8)

The information processing method according to Supplementary Note 7, in which
in the presetting step, the initial value is set by setting a prior distribution such that a probability changes according to a value, and
in the simulation data evaluation step, evaluation is performed by calculating similarity indicating similarity between a value of the observation data including a value obtained by the prior distribution of the missing portion and data obtained in the simulation.

### (Supplementary Note 9)

The information processing method according to Supplementary Note 8, in which
in the presetting step, the prior distribution is set such that the probability is constant from a lower limit value to a first value, and the probability is decreased from the first value to the upper limit value as a possible value of the observation data.

### (Supplementary Note 10)

The information processing method according to Supplementary Note 8, in which
in the presetting step, the prior distribution is set such that the probability is maximized in a case where the observation data has the same value as a measurement value obtained by a sensor different from the sensor, the probability is increased from a lower limit value to the same value, and the probability is decreased from the same value to an upper limit value.

### (Supplementary Note 11)

The information processing method according to Supplementary Note 7, in which
in the missing value estimation step, the missing portion of the observation data is replaced with the estimated value.

### (Supplementary Note 12)

The information processing method according to Supplementary Note 8, in which
a sensor is a sensing device using an optical fiber cable laid on a road,
the observation data is average speed data indicating an average speed of vehicles traveling on the road calculated using data from the optical fiber cable, and
in the presetting step, the prior distribution is set such that the probability changes according to the average speed of the vehicles.

### (Supplementary Note 13)

A computer-readable recording medium recording a program including commands for causing
a computer to execute:
a presetting step of setting an initial value of a missing portion in observation data output from a sensor;
a simulation data evaluation step of acquiring results of a plurality of simulations executed assuming an observation environment, and evaluating, for each of the simulations, similarity between the observation data including the missing portion and data obtained in the simulation; and
a missing value estimation step of estimating a value of the missing portion using data obtained in the simulation having the highest similarity.

### (Supplementary Note 14)

The computer-readable recording medium according to Supplementary Note 13, in which
the program causes the computer to execute:
in the presetting step, setting the initial value by setting a prior distribution such that a probability changes according to a value; and
in the simulation data evaluation step, performing evaluation by calculating similarity indicating similarity between a value of the observation data including a value obtained by the prior distribution of the missing portion and data obtained in the simulation.

### (Supplementary Note 15)

The computer-readable recording medium according to Supplementary Note 14, in which
the program causes the computer to execute,
in the presetting step, setting the prior distribution such that the probability is constant from a lower limit value to a first value, and the probability is decreased from the first value to an upper limit value as a possible value of the observation data.

### (Supplementary Note 16)

The computer-readable recording medium according to Supplementary Note 14, in which
the program causes the computer to execute,
in the presetting step, setting the prior distribution such that the probability is maximized in a case where the observation data has the same value as a measurement value obtained by a sensor different from the sensor, the probability is increased from a lower limit value to the same value, and the probability is decreased from the same value to an upper limit value.

### (Supplementary Note 17)

The computer-readable recording medium according to Supplementary Note 13, in which
the program causes the computer to execute,
in the missing value estimation step, replacing the missing portion of the observation data with the estimated value.

### (Supplementary Note 18)

The computer-readable recording medium according to Supplementary Note 14, in which
a sensor is a sensing device using an optical fiber cable laid on a road,
the observation data is average speed data indicating an average speed of vehicles traveling on the road calculated using data from the optical fiber cable, and
the program causes the computer to execute,
in the presetting step, setting a prior distribution such that the probability changes according to the average speed of the vehicles.

While the present invention has been particularly shown and described with reference to example embodiments thereof, the present invention is not limited to these example embodiments. It will be understood by those of ordinary skill in the art that various changes in form and details may be made therein without departing from the spirit and scope of the present invention as defined by the claims.

As described above, according to the present disclosure, in a case where a missing portion occurs in observation data acquired from a sensor, it is possible to compensate for the missing portion. The present disclosure is useful for a system that performs management based on observation data from a sensor, for example, a road management system.

1. An information processing apparatus comprising:
at least one memory storing instructions; and
at least one processor configured to execute the instructions to:
set an initial value of a missing portion in observation data output from a sensor;
acquire results of a plurality of simulations executed assuming an observation environment, and evaluate, for each of the simulations, similarity between the observation data including the missing portion and data obtained in the simulation; and
estimate a value of the missing portion using data obtained in the simulation having the highest similarity.

2. The information processing apparatus according to claim 1, wherein
at least one processor sets the initial value by setting a prior distribution such that a probability changes according to a value, and
performs evaluation by calculating similarity indicating similarity between a value of the observation data including a value obtained by the prior distribution of the missing portion and data obtained in the simulation.

3. The information processing apparatus according to claim 2, wherein
at least one processor sets the prior distribution such that the probability is constant from a lower limit value to a first value, and the probability is decreased from the first value to an upper limit value as a possible value of the observation data.

4. The information processing apparatus according to claim 2, wherein
at least one processor sets the prior distribution such that the probability is maximized in a case where the observation data has the same value as a measurement value obtained by a sensor different from the sensor, the probability is increased from a lower limit value to the same value, and the probability is decreased from the same value to an upper limit value.

5. The information processing apparatus according to claim 1, wherein
at least one processor replaces the missing portion of the observation data with the estimated value.

6. The information processing apparatus according to claim 2, wherein
a sensor is a sensing device using an optical fiber cable laid on a road,
the observation data is average speed data indicating an average speed of vehicles traveling on the road calculated using data from the optical fiber cable, and
at least one processor sets a prior distribution such that the probability changes according to the average speed of the vehicles.

7. An information processing method comprising:
setting an initial value of a missing portion in observation data output from a sensor;
acquiring results of a plurality of simulations executed assuming an observation environment, and evaluating, for each of the simulations, similarity between the observation data including the missing portion and data obtained in the simulation; and
estimating a value of the missing portion using data obtained in the simulation having the highest similarity.

8. The information processing method according to claim 7, wherein
in the setting of the initial value, the initial value is set by setting a prior distribution such that a probability changes according to a value; and
in the evaluation of the simulation data, evaluation is performed by calculating similarity indicating similarity between a value of the observation data including a value obtained by the prior distribution of the missing portion and data obtained in the simulation.

9. The information processing method according to claim 8, wherein
in setting of the initial value, the prior distribution is set such that the probability is constant from a lower limit value to a first value, and the probability is decreased from the first value to an upper limit value as a possible value of the observation data.

10. The information processing method according to claim 8, wherein
in the setting of the initial value, the prior distribution is set such that the probability is maximized in a case where the observation data has the same value as a measurement value obtained by a sensor different from the sensor, the probability is increased from a lower limit value to the same value, and the probability is decreased from the same value to an upper limit value.

11. The information processing method according to claim 7, wherein
in the estimation of the value of the missing portion, the missing portion of the observation data is replaced with the estimated value.

12. The information processing method according to claim 8, wherein
a sensor is a sensing device using an optical fiber cable laid on a road,
the observation data is average speed data indicating an average speed of vehicles traveling on the road calculated using data from the optical fiber cable, and
in the setting of the initial value, a prior distribution is set such that the probability changes according to the average speed of the vehicles.

13. A non-transitory computer-readable recording medium recording a program causing
a computer to execute:
setting an initial value of a missing portion in observation data output from a sensor;
acquiring results of a plurality of simulations executed assuming an observation environment, and evaluating, for each of the simulations, similarity between the observation data including the missing portion and data obtained in the simulation; and
estimating a value of the missing portion using data obtained in the simulation having the highest similarity.

14. The non-transitory computer-readable recording medium according to claim 13, wherein
the program causes the computer to execute:
in the setting of the initial value, setting the initial value by setting a prior distribution such that a probability changes according to a value; and
in the evaluation of the simulation data, performing evaluation by calculating similarity indicating similarity between a value of the observation data including a value obtained by the prior distribution of the missing portion and data obtained in the simulation.

15. The non-transitory computer-readable recording medium according to claim 14, wherein
the program causes the computer to execute,
in the setting of the initial value, setting the prior distribution such that the probability is constant from a lower limit value to a first values, and the probability is decreased from the first value to an upper limit value as a possible value of the observation data.

16. The non-transitory computer-readable recording medium according to claim 14, wherein
the program causes the computer to execute,
in the setting of the initial value, setting the prior distribution such that the probability is maximized in a case where the observation data has the same value as a measurement value obtained by a sensor different from the sensor, the probability is increased from a lower limit value to the same value, and the probability is decreased from the same value to an upper limit value.

17. The non-transitory computer-readable recording medium according to claim 13, wherein
the program causes the computer to execute,
in the estimation of the value of the missing portion, replacing the missing portion of the observation data with the estimated value.

18. The non-transitory computer-readable recording medium according to claim 14, wherein
a sensor is a sensing device using an optical fiber cable laid on a road,
the observation data is average speed data indicating an average speed of vehicles traveling on the road calculated using data from the optical fiber cable, and
the program causes the computer to execute,
in the setting of the initial value, setting a prior distribution such that the probability changes according to the average speed of the vehicles.
